(19) United States
(12) Patent Application Publication
(10) Pub. No.: US 2026/0033003 A1
(43) Pub. Date: Jan. 29, 2026

(54) DISPLAY PANEL AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN); BEIJING BOE TECHNOLOGY DEVELOPMENT CO., LTD., Beijing (CN)

(72) Inventors: Qiujie SU, BEIJING (CN); Dongchuan CHEN, BEIJING (CN); Yingmeng MIAO, BEIJING (CN); Xiaofeng YIN, BEIJING (CN)

(73) Assignees: BEIJING BOE DISPLAY TECHNOLOGY CO., LTD., Beijing (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/994,843

(22) PCT Filed: May 14, 2024
(86) PCT No.: PCT/CN2024/093106

§ 371 Date: Jan. 15, 2025

(30) Foreign Application Priority Data
Jun. 2, 2023 (CN) 202310653611.5

(51) Int. Cl. H10D 86/40; H10D 86/60

(52) U.S. Cl. CPC H10D 86/441; H10D 86/60

(57) ABSTRACT

The present disclosure provides a display panel and a display device. The display panel includes: a base substrate; a display layer and a sensor layer on the base substrate, wherein the display layer includes a plurality of sub-pixel groups, each sub-pixel group includes a plurality of sub-pixels, the sensor layer includes a plurality of sensor groups, each sensor group includes a plurality of sensors, the plurality of sensors include one or more columns of first sensors arranged in a first direction and one or more columns of second sensors arranged in the first direction, each column of first sensors includes a plurality of first sensors, each column of second sensors includes a plurality of second sensors; and a plurality of integrated circuit elements.

### CROSS-REFERENCE TO RELATED APPLICATIONS

The present application is a U.S. National Stage Application under 35 U.S.C. § 371 of International Patent Application No. PCT/CN2024/093106, filed on May 14, 2024, which is based on and claims priority to China Patent Application No. 202310653611.5 filed on Jun. 2, 2023, the disclosure of both of which are incorporated by reference herein in entirety.

### TECHNICAL FIELD

The present disclosure relates to a display panel and a display device.

### BACKGROUND

In the related art, a display panel may have display and touch functions. The display panel comprises an IC (Integrated Circuit) element electrically connected to sub-pixels in a display area through a part of fanout lines, and electrically connected to a sensor (which may also be referred to as a sensor block) for implementing a touch function through another part of fanout lines.

FIGS. 1A to 1C are schematic views showing pins of an integrated circuit element of a display panel in some embodiments of the related art. FIGS. 1A to 1C show a plurality of first pins (also referred to as data pins) 110 and a plurality of second pins (also referred to as touch pins) 120 of an integrated circuit element respectively, wherein the plurality of first pins 110 are electrically connected to the sub-pixels through a part of fanout lines, and the plurality of second pins 120 are electrically connected to a sensor through another part of fanout lines.

As shown in FIG. 1A, the plurality of first pins 110 comprise two parts of first pins 110, and the plurality of second pins 120 are between the two parts of first pins 110. As shown in FIG. 1B, the plurality of second pins 120 comprise two parts of second pins 120, and the plurality of first pins 110 are between the two parts of second pins 120. As shown in FIG. 1C, the plurality of first pins 110 and the plurality of second pins 120 are staggered.

FIG. 2 is a schematic view showing distribution of sensors of a display panel in the related art. As shown in FIG. 2, the display panel comprises IC elements 130 and a sensor array wherein the sensor array comprises a plurality of sensors 135. Each IC element is connected to a part of the plurality of sensors 135. FIG. 2 also shows a first direction 101 and a second direction 102.

### SUMMARY

According to an aspect of the present disclosure, a display panel is provided. The display panel comprises: a base substrate; a display layer and a sensor layer on the base substrate, wherein the display layer comprises a plurality of sub-pixel groups, each of the plurality of sub-pixel groups comprises a plurality of sub-pixels, the sensor layer comprises a plurality of sensor groups, each of the plurality of sensor groups comprises a plurality of sensors, and the plurality of sensors comprises one or more columns of first sensors arranged along a first direction and one or more columns of second sensors arranged along the first direction, wherein each column of first sensors of the one or more columns of first sensors comprises a plurality of first sensors, each column of second sensors of the one or more columns of second sensors comprises a plurality of second sensors, an orthographic projection of each first sensor of the plurality of first sensors on the base substrate overlaps with an orthographic projection of a first number of columns of sub-pixels on the base substrate, and an orthographic projection of each second sensor of the plurality of second sensors on the base substrate overlaps with an orthographic projection of a second number of columns of sub-pixels on the base substrate, wherein the first number of columns is greater than the second number of columns; and a plurality of integrated circuit elements, wherein the plurality of integrated circuit elements are electrically connected to the plurality of sub-pixel groups in one-to-one correspondence, and each integrated circuit element of the plurality of integrated circuit elements is electrically connected to the plurality of sub-pixels in a sub-pixel group electrically connected to the each integrated circuit element, and the plurality of integrated circuit elements are electrically connected to the plurality of sensor groups in one-to-one correspondence, and the each integrated circuit element is electrically connected to the plurality of sensors in a sensor group electrically connected to the each integrated circuit element.

In some embodiments, an orthographic projection of each of the plurality of sensors on the base substrate overlaps with an orthographic projection of a part of sub-pixels in the plurality of sub-pixels on the base substrate.

In some embodiments, a length of the each first sensor in the first direction is greater than a length of the each second sensor in the first direction.

In some embodiments, the one or more columns of first sensors comprise a plurality of columns of first sensors, and the one or more columns of second sensors are on at least one side of the plurality of columns of first sensors, or the one or more columns of second sensors are at an intermediate position of the plurality of columns of first sensors; or the one or more columns of first sensors comprise a plurality of columns of first sensors, and the one or more columns of second sensors comprise a plurality of columns of second sensors, wherein one part of columns of second sensors in the plurality of columns of second sensors are between one part of columns of first sensors in the plurality of columns of first sensors, and another part of columns of second sensors in the plurality of columns of second sensors are between another part of columns of first sensors in the plurality of columns of first sensors.

In some embodiments, the each column of first sensors comprises at least one first sub-sensor and at least one second sub-sensor, wherein an orthographic projection of each first sub-sensor of the at least one first sub-sensor on the base substrate overlaps with an orthographic projection of a first number of rows of sub-pixels on the base substrate, and an orthographic projection of each second sub-sensor of the at least one second sub-sensor on the base substrate overlaps with an orthographic projection of a second number of rows of sub-pixels on the base substrate, wherein the first number of rows is greater than the second number of rows.

In some embodiments, the each column of second sensors comprises at least one third sub-sensor and at least one fourth sub-sensor, wherein an orthographic projection of each third sub-sensor of the at least one third sub-sensor on the base substrate overlaps with an orthographic projection of a third number of rows of sub-pixels on the base substrate, and an orthographic projection of each fourth sub-sensor of the at least one fourth sub-sensor on the base substrate overlaps with an orthographic projection of a fourth number of rows of sub-pixels on the base substrate, wherein the third number of rows is greater than the fourth number of rows.

In some embodiments, the each first sub-sensor and the each third sub-sensor are in a same row, and the first number of rows is equal to the third number of rows; and the each second sub-sensor and the each fourth sub-sensor are in a same row, and the second number of rows is equal to the fourth number of rows.

In some embodiments, a length of the each first sub-sensor in a second direction is greater than a length of the each second sub-sensor in the second direction, wherein the second direction intersects with the first direction.

In some embodiments, a length of the each third sub-sensor in a second direction is greater than a length of the each fourth sub-sensor in the second direction, wherein the second direction intersects with the first direction.

In some embodiments, a ratio C of a difference between the first number A of columns and the second number B of columns to the first number A of columns is less than a predetermined value, where

$$C = \frac{A - B}{A} \times 100 \% .$$

In some embodiments, a number of columns of the one or more columns of first sensors is greater than or equal to a number of columns of the one or more columns of second sensors.

In some embodiments, a number of the plurality of integrated circuit elements is D, where D is a positive integer; the sensor layer comprises E column of sensors, where E is a positive even number; and the each integrated circuit element is electrically connected to N columns of sensors, where

$$N = \frac{E}{D}$$

and N is a positive even number.

In some embodiments, the display panel is a display panel with a single-gate line, and a number of columns of sub-pixels of the display panel is equal to a number of a plurality of data lines electrically connected to the sub-pixels of the display panel; a number of the plurality of integrated circuit elements is D, where D is a positive integer; a horizontal resolution of the display panel is H₁ pixels, where H₁ is a positive integer, and each of the H₁ pixels comprises three sub-pixels with different colors; and the each integrated circuit element is electrically connected to at least a part of the plurality of data lines through a plurality of pins, wherein a number of the plurality of pins is M₁, M₁ is a positive integer, and

$${M}_{1} = \frac{{H}_{1} * 3}{D} .$$

In some embodiments, the display panel is a display panel with a dual-gate line, and a number of columns of sub-pixels of the display panel is twice a number of a plurality of data lines electrically connected to the sub-pixels of the display panel; a number of the plurality of integrated circuit elements is D, where D is a positive integer; a horizontal resolution of the display panel is H₂ pixels, where H₂ is a positive integer, and each of the H₂ pixels comprises three sub-pixels with different colors; and the each integrated circuit element is electrically connected to at least a part of the plurality of data lines through a plurality of pins, wherein a number of the plurality of pins is M₂, M₂ is a positive integer, and

$${M}_{2} = \frac{{H}_{2} * 3}{2 * D} .$$

In some embodiments, the display panel is a display panel with a triple-gate line, and a number of columns of pixels of the display panel is equal to a number of a plurality of data lines electrically connected to the pixels of the display panel; a number of the plurality of integrated circuit elements is D, where D is a positive integer; a horizontal resolution of the display panel is H₃ pixels, where H₃ is a positive integer, and each of the H₃ pixels comprises three sub-pixels with different colors; and the each integrated circuit element is electrically connected to at least a part of the plurality of data lines through a plurality of pins, wherein a number of the plurality of pins is M₃, M₃ is a positive integer, and

$${M}_{3} = \frac{{H}_{3}}{D} .$$

In some embodiments, the each integrated circuit element is electrically connected to the plurality of sub-pixels through a plurality of first wires, and the each integrated circuit element is electrically connected to the plurality of sensors through a plurality of second wires, wherein the plurality of first wires and the plurality of second wires are in different layers or in a same layer.

In some embodiments, numbers of the plurality of first wires electrically connected to any two of the plurality of integrated circuit elements are equal; and numbers of the plurality of second wires electrically connected to any two of the plurality of integrated circuit elements are equal.

In some embodiments, areas of any two of the plurality of sensor groups are equal.

According to another aspect of the present disclosure, a display device is provided. The display device comprises the display panel as described previously.

Other features and advantages of the present disclosure will become explicit from the following detailed description of exemplary embodiments of the present disclosure with reference to the accompanying drawings.

### BRIEF DESCRIPTION OF THE DRAWINGS

The accompanying drawings which constitute part of this specification, describe the embodiments of the present disclosure, and together with this specification, serve to explain the principles of the present disclosure.

The present disclosure may be more explicitly understood from the following detailed description with reference to the accompanying drawings, in which:

FIG. 1A is a schematic view showing pins of an integrated circuit element of a display panel in an embodiment of the related art;

FIG. 1B is a schematic view showing pins of an integrated circuit element of a display panel in another embodiment of the related art;

FIG. 1C is a schematic view showing pins of an integrated circuit element of a display panel in another embodiment of the related art;

FIG. 2 is a schematic view showing distribution of sensors of a display panel in the related art;

FIG. 3 is a schematic view showing a display panel in the related art;

FIG. 4 is a diagram showing distribution of capacitance values of parasitic capacitances caused by touch fanout lines and data fanout lines of the display panel in the related art;

FIG. 5 is a schematic sectional view showing a display panel according to an embodiment of the present disclosure;

FIG. 6 is a schematic view showing distribution of sensors of a display panel according to an embodiment of the present disclosure;

FIG. 7 is a schematic view showing distribution of sensors in a sensor group according to an embodiment of the present disclosure;

FIG. 8 is an enlarged schematic view showing several sensors according to an embodiment of the present disclosure;

FIG. 9 is a schematic view showing a display panel according to an embodiment of the present disclosure;

FIG. 10A is a schematic view showing a plurality of first wires and a plurality of second wires of a display panel according to an embodiment of the present disclosure;

FIG. 10B is a schematic view showing a plurality of first wires and a plurality of second wires of a display panel according to another embodiment of the present disclosure;

FIG. 10C is a schematic view showing a plurality of first wires and a plurality of second wires of a display panel according to another embodiment of the present disclosure;

FIG. 11 is a schematic view showing distribution of sensors in a sensor group according to another embodiment of the present disclosure;

FIG. 12 is a schematic view showing distribution of sensors in a sensor group according to another embodiment of the present disclosure;

FIG. 13A is a schematic view showing arrangement of sub-pixels of a display panel according to an embodiment of the present disclosure;

FIG. 13B is a schematic view showing arrangement of sub-pixels of a display panel according to another embodiment of the present disclosure;

FIG. 13C is a schematic view showing arrangement of sub-pixels of a display panel according to another embodiment of the present disclosure.

It should be understood that, the dimensions of various parts shown in the accompanying drawings are not drawn according to actual proportional relations. In addition, the same or similar components are denoted by the same or similar reference signs.

### DETAILED DESCRIPTION

Various exemplary embodiments of the present disclosure will now be described in detail in conjunction with the accompanying drawings. The description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”. “include”, or the like means that the element before the word covers the element(s) listed after the word without excluding the possibility of also covering other elements. The terms “up”, “down”, “left”, “right”, or the like are used only to represent a relative positional relationship, and the relative positional relationship may be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to the other devices without an intermediate device, and alternatively, may not be directly connected to the other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

The inventors of the present disclosure have found that, the number of first pins and the number of second pins of an integrated circuit element might be limited by the support capability of the integrated circuit element, which are specifically as follows:

In the related art, the number of first pins that can be supported by each IC element usually only supports several number modes, but does not support any adjustment, for example, it can support 720 first pins at most.

The number of first pins of the IC element may select a mode such as 480-pin (that is, 480 pins), 576-pin (that is, 576 pins) or 720-pin (that is, 720 pins). At present, the total number of first pins required for products in the related art is one of several modes. For example, for a display panel product with a dual-gate line with a display resolution of UHD (Ultra High Definition), a horizontal resolution PH of the pixel resolution of the display panel is 3840, and one pixel contains three sub-pixels, that is, a red sub-pixel R, a green sub-pixel G and a blue sub-pixel B. Due to the architectural characteristics of the display panel with a dual-gate line, every two columns of sub-pixels share one data line. Therefore, the total number of first pins required is 3840*3/2-5760, so that the number of IC elements required is 5760/720=8 (select a 720-pin mode here) or 5760/576=10 (select a 576-pin mode here).

For a relatively special resolution, for example, a display panel product with a dual-gate line with a resolution of 3000*2000, one pixel comprises three sub-pixels, that is, a red sub-pixel R, a green sub-pixel G and a blue sub-pixel B. and the total number of first pins required is 3000*3/2=4500. In these alternative modes of 480-pin, 576-pin or 720-pin, it is impossible to achieve consistent numbers of pins driven by each IC element. The general solution is that the first few IC elements adopt one of the modes, and the last IC element may not adopt the number of these modes. For example, the driving solution is to use 8 IC elements, the first 7 IC elements all use a 576-pin mode, and the last IC element uses 4500-576*7=468 pins. For example, the last IC element also selects a 576 mode, but only uses 468 pins.

Furthermore, the number of columns of sensors (that is, sensor blocks) driven by each IC element is an even number, that is, the horizontal resolution SH of sensors is an even number, and the ratio of the horizontal resolution SH of sensors to the number of IC elements is an even number. Moreover, the number of sensors driven by each IC element is consistent.

With these restrictions of IC elements, the sensor block mode is not arbitrary. For some special resolutions, the sensor block solution needs a special design.

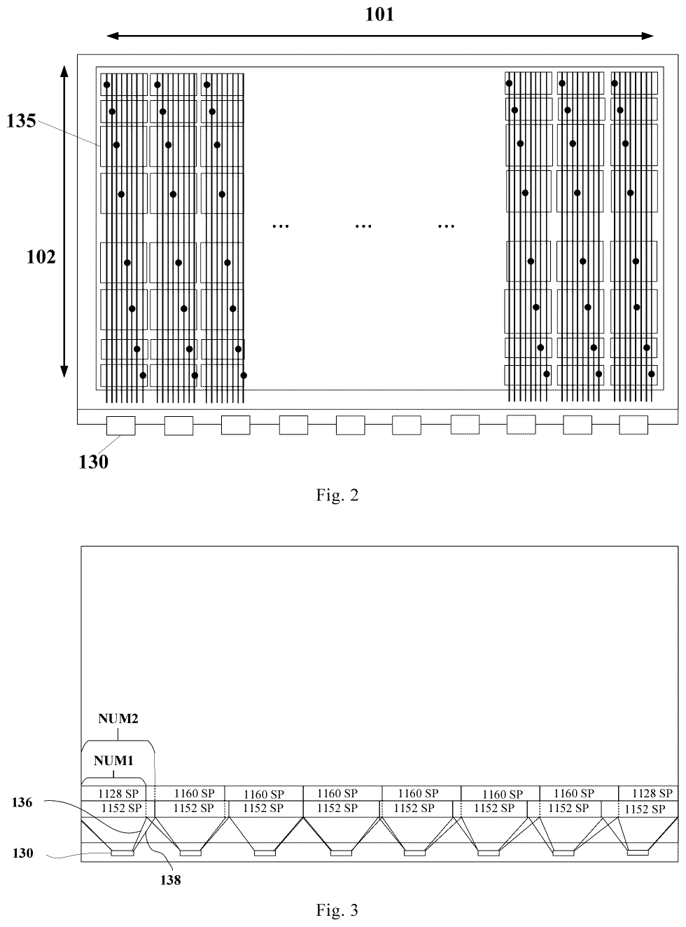

For example, the horizontal resolution of the pixel resolution is 3072, and the number of data lines is 3072*3/2=4608. If an IC element with a 576-pin mode is selected, 8 IC elements are required, and each IC element has 4608/8-576 pins, SH/8=N, N is an even number, and N may be selected as 6, 8, 10, 12 or the like. For example, considering the dimensions of sensors comprehensively, N is selected as 10, and each sensor corresponds to a specific number of pixels in the horizontal direction (referred to as H direction for short, such as the first direction 101 shown in FIG. 2) and the vertical direction (referred to as V direction for short, such as the second direction 102 shown in FIG. 2). If SH=80, then the number of sub-pixels corresponding to each sensor in the horizontal direction is 3072*3/80=115.2, and the number of sub-pixels cannot be divisible. Therefore, in the horizontal direction, the sensors on the whole panel cannot be equally divided. The sensors are distributed in such a way that the undivided parts are placed on the edges of the panel, for example, the upper and lower edges, or the left and right edges.

If the total number of pixels in the horizontal direction of the display panel cannot be divided by the number of sensors in the horizontal direction, the parts that cannot be divided are placed on the left and right edges of the display panel. With the restrictions of IC elements, the display panel corresponds to 80 columns of sensors in the horizontal direction, wherein each sensor in 78 columns of sensors corresponds to 116 sub-pixels in the horizontal direction, and each sensor in the other two columns of sensors corresponds to 84 sub-pixels in the horizontal direction, and these two columns of sensors are distributed on the left and right edges of the panel respectively.

However, such distribution will lead to the following problem: each IC element drives 576 first pins, corresponding to 1152 (that is, 576*2=1152) sub-pixels in the horizontal direction of an active area (that is, a display area). Sensors driven by each IC element are 10 columns and 56 rows of sensors, with a total of 10*56=560 sensors, which also meets the requirements of IC elements. The difficulty lies in that each column of sensors on the left and right edges of the panel only correspond to 84 sub-pixels in the horizontal direction. In this way, touch signal lines of each of the first IC element and the eighth IC element correspond to 1128 (that is, 1*84+9*116=1128) sub-pixels in the horizontal direction of the active area, and the touch signal lines of each of the 6 IC elements in the middle correspond to 1160 (that is, 10*116=1160) sub-pixels in the horizontal direction of the active area. The active area corresponding to the plurality of first pins driven by each IC element has 1152 sub-pixels in the horizontal direction, so that the touch signal line and the data signal line of one IC element correspond to different pixel numbers respectively, and the signal lines are led out from the pixel display area to the pins of the IC element. For the first column and last column of sensors of the whole panel, 56 touch signal lines are required to be led out from 84 sub-pixels, while for the middle 78 columns of sensors of the whole panel, 56 signal lines are required to be led out from 116 sub-pixels. Considering that the touch signal lines have the influence of reducing the aperture ratio of pixels, if one signal line is led out between two sub-pixels, it is only possible to lead out 42 touch signal lines from 84 sub-pixels, which cannot meet the lead requirements of 56 sensors in the vertical direction. Even at the expense of the pixel aperture ratio, each sub-pixel leads out one signal line, and 84 sub-pixels may lead out 84 signal lines, which meets the lead requirements of 56 sensors in the vertical direction. As mentioned previously, the touch driving signal line and the data signal line of such an IC element correspond to different pixel numbers respectively, and the signal lines are led out from the pixel display area to the pins of the IC element, and the leads connected to the pins of the IC element from the touch signal line and the data signal line of the pixel area present fan-shaped lines as a whole, referred to as fanout lines, which are divided into touch fanout lines and data fanout lines.

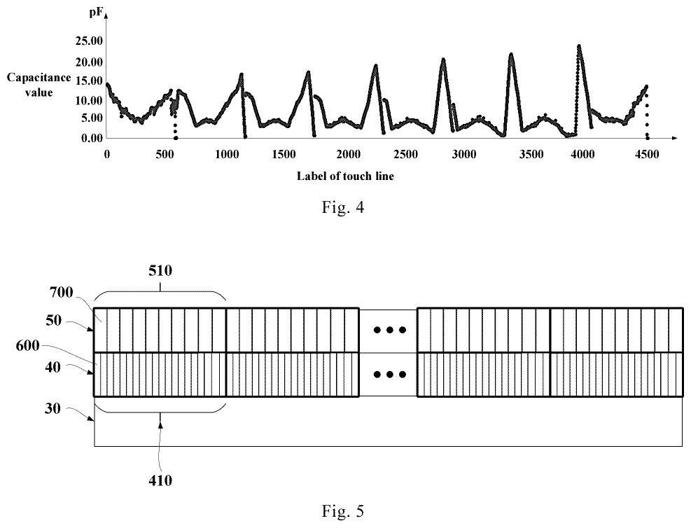

FIG. 3 is a schematic view showing a display panel in the related art. FIG. 3 shows an IC element 130, a touch fanout line 136 and a data fanout line 138. In FIG. 3, SP represents a sub-pixel. As shown in FIG. 3, the sensors driven by each of the first IC element and the eighth IC element correspond to 1128 (that is, NUM1) columns of sub-pixels, and the sensors driven by each of the middle six IC elements correspond to 1160 columns of sub-pixels, and each IC element 130 drives 1152 (NUM2) columns of sub-pixels.

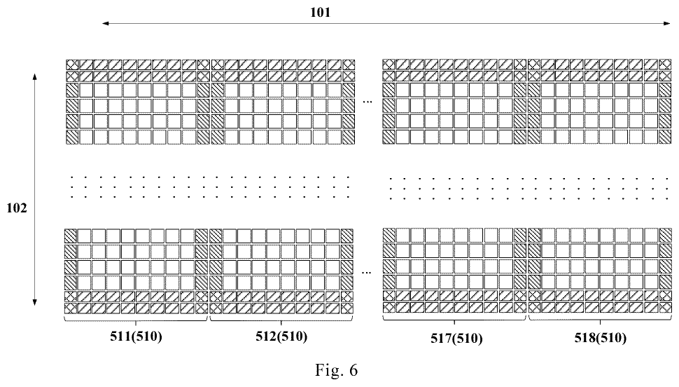

As may be seen from FIG. 3, the touch fanout lines and the data fanout lines of different IC elements 130 might intersect with each other, which require that the touch fanout lines and the data fanout lines are in different layers. As shown in FIG. 4, the sizes of parasitic capacitances generated by the intersection of the touch fanout lines and the data fanout lines at different positions might be different, which leads to different capacitance values of the parasitic capacitances at different positions, so that it is likely to result in abnormal display of the display panel.

In view of this, the embodiment of the present disclosure provides a display panel, so as to make the capacitance values of the parasitic capacitances generated by the intersection of the touch fanout lines and the data fanout lines at different positions equal as much as possible, thereby improving the display effect of the display panel.

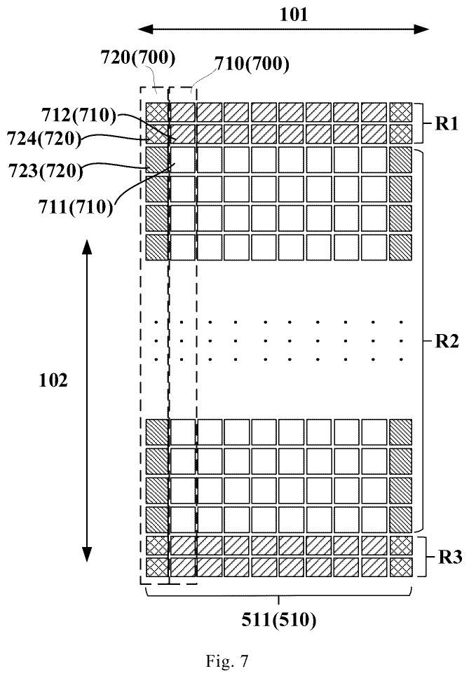

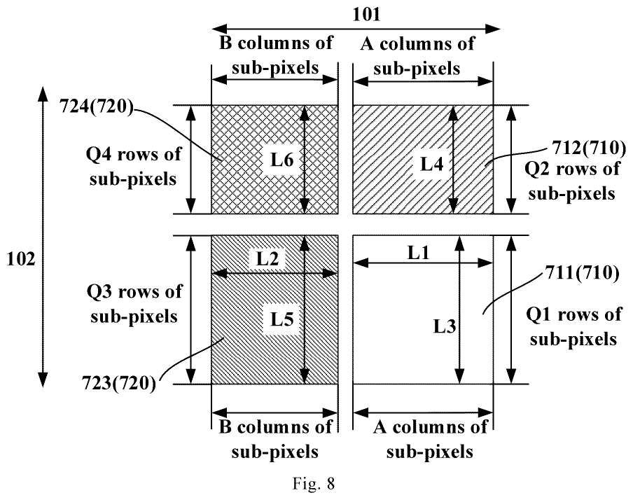

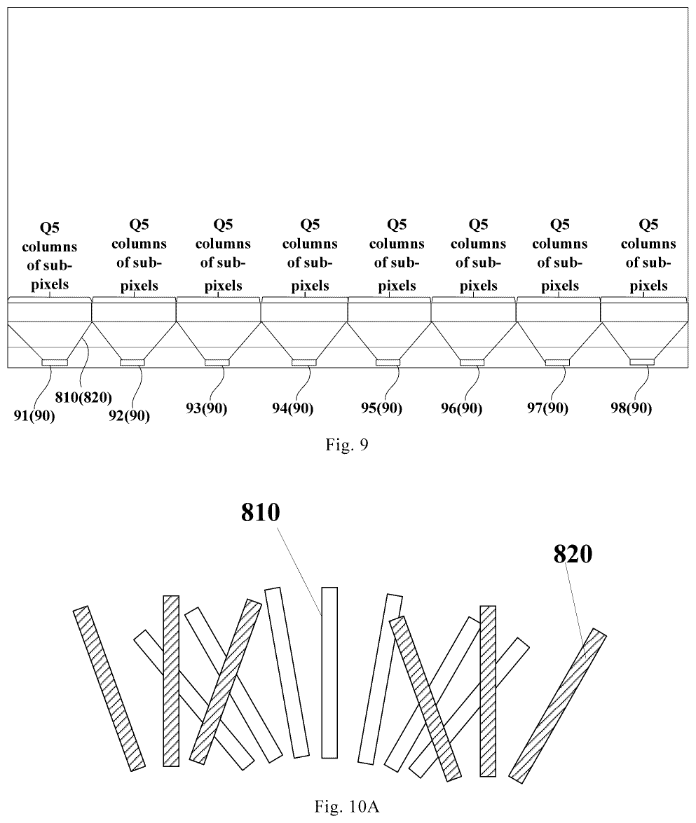

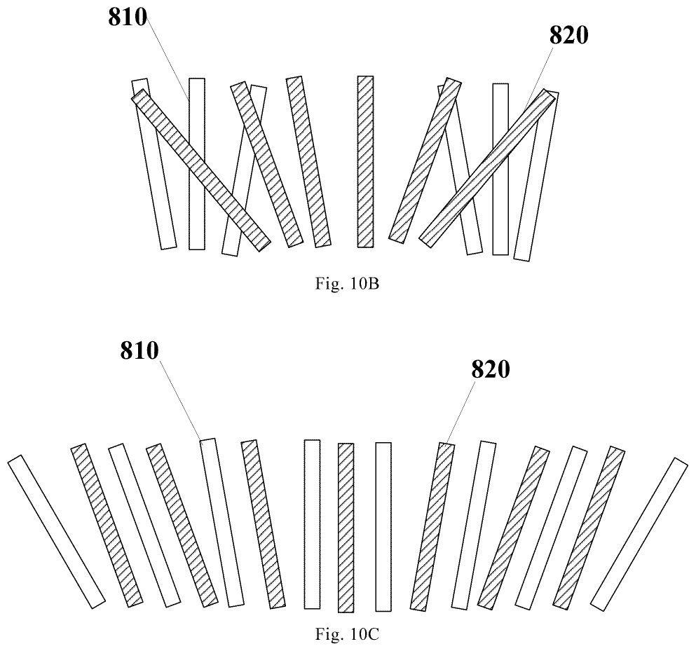

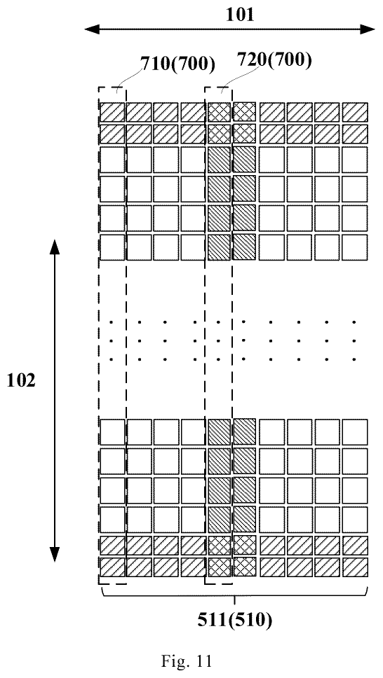

FIG. 5 is a schematic sectional view showing a display panel according to an embodiment of the present disclosure. FIG. 6 is a schematic view showing distribution of sensors of a display panel according to an embodiment of the present disclosure. FIG. 7 is a schematic view showing distribution of sensors in a sensor group according to an embodiment of the present disclosure. FIG. 8 is an enlarged schematic view showing several sensors according to an embodiment of the present disclosure. FIG. 9 is a schematic view showing a display panel according to an embodiment of the present disclosure. A display panel according to some embodiments of the present disclosure will be described in detail below in conjunction with these accompanying drawings.

As shown in FIG. 5, the display panel comprises a base substrate 30. The base substrate 30 may be a flexible substrate or a rigid substrate.

As shown in FIG. 5, the display panel further comprises a display layer 40 and a sensor layer 50 on the base substrate 30. For example, the display layer 40 and the sensor layer 50 are arranged in a direction perpendicular to the base substrate 30. For example, as shown in FIG. 5, the display layer 40 is between the sensor layer 50 and the base substrate 30. For another example, the sensor layer 50 is between the display layer 40 and the base substrate 30. For another example, the base substrate 30 is between the display layer 40 and the sensor layer 50. Therefore, the scope of the embodiment of the present disclosure is not limited to a specific positional relationship among the base substrate 30, the display layer 40 and the sensor layer 50, as long as the base substrate 30, the display layer 40 and the sensor layer 50 are arranged in the direction perpendicular to the base substrate 30.

It is to be noted that in some embodiments, the display layer 40 and the sensor layer 50 may share some structural layers. For example, the structural layer is a common electrode layer, wherein the common electrode layer may be used as a layer in the display layer or a layer in the sensor layer. The shared structural layer (for example, the common electrode layer) may be subjected to time division multiplexing. For example, when the display panel performs a display function, the shared structural layer serves as an electrode of the display layer, and when the display panel performs a touch scanning function, the shared structural layer is used as a layer in the touch sensor.

Of course, those skilled in the art can understand that the scope of the embodiment of the present disclosure is not limited thereto. For example, in other embodiments, the display layer 40 and the sensor layer 50 may be two separate structures, that is, the display layer 40 and the sensor layer 50 may not share a structural layer.

As shown in FIG. 5, the display layer 40 comprises a plurality of sub-pixel groups 410. For example, the plurality of sub-pixel groups 410 comprise a plurality of sub-pixel groups 410. Each sub-pixel group 410 comprises a plurality of sub-pixels 600. As shown in FIGS. 5 and 6, the sensor layer comprises a plurality of sensor groups 510. For example, the plurality of sensor groups 510 comprises a plurality of sensor groups 510. Each sensor group 510 comprises a plurality of sensors 700. For example, as shown in FIG. 6, the plurality of sensor groups 510 comprise sensor groups 511, 512, . . . 517 and 518.

As shown in FIGS. 6 and 7, in each sensor group 510, the plurality of sensors comprise: one or more columns of first sensors 710 arranged along a first direction 101 and one or more columns of second sensors 720 arranged along the first direction 101, wherein each column of first sensors 710 comprise a plurality of first sensors 710 and each column of second sensors 720 comprise a plurality of second sensors 720. An orthographic projection of each first sensor 710 on the base substrate 30 overlaps with an orthographic projection of a first number of columns of sub-pixels on the base substrate 30, and an orthographic projection of each second sensor 720 on the base substrate 30 overlaps with an orthographic projection of a second number of columns of sub-pixels on the base substrate 30, wherein the first number of columns is greater than the second number of columns. For example, the first direction 101 is a horizontal direction, that is, a row direction of a sensor array or a sub-pixel array.

For example, as shown in FIG. 8, an orthographic projection of a certain first sensor 710 on the base substrate 30 overlaps with an orthographic projection of a first number A of columns of sub-pixels on the base substrate 30, that is, the certain first sensor 710 is arranged corresponding to the first number A of columns of sub-pixels. For another example, an orthographic projection of a certain second sensor 720 on the base substrate 30 overlaps with an orthographic projection of a second number B of columns of sub-pixels on the base substrate 30, that is, the certain second sensor 720 is arranged corresponding to the second number B of columns of sub-pixels. Here, the first number A of columns is greater than the second number B of columns. For example, A=116 and B=112.

It is to be noted that in the embodiment of the present disclosure, the sub-pixels arranged along a second direction 102 are referred to as a column of sub-pixels, and the sub-pixels arranged along a first direction 101 are referred to as a row of sub-pixels. The second direction 102 intersects with the first direction 101. For example, the second direction is perpendicular to the first direction. For example, the second direction 102 is a vertical direction, that is, a column direction of the sensor array or the sub-pixel array.

As shown in FIG. 9, the display panel further comprises a plurality of integrated circuit elements 90. For example, FIG. 9 shows eight integrated circuit elements 91, 92, 93, 94, 95, 96, 97 and 98. For example, the integrated circuit element is an integrated circuit chip. The plurality of integrated circuit elements 90 are electrically connected to the plurality of sub-pixel groups 410 in one-to-one correspondence, and each integrated circuit element 90 is electrically connected to the plurality of sub-pixels 600 in the sub-pixel group electrically connected to the each integrated circuit element. That is, each integrated circuit element 90 is electrically connected to the plurality of sub-pixels 600 in a sub-pixel group corresponding to the each integrated circuit element. The plurality of integrated circuit elements 90 are electrically connected to the plurality of sensor groups 510 in one-to-one correspondence, and each integrated circuit element is electrically connected to the plurality of sensors 700 in the sensor group electrically connected to the each integrated circuit element. That is, each integrated circuit element is electrically connected to the plurality of sensors 700 in a sensor group corresponding to the each integrated circuit element.

So far, a display panel according to some embodiments of the present disclosure has been provided. The display panel comprises: a base substrate; a display layer and a sensor layer on the base substrate, wherein the display layer comprises a plurality of sub-pixel groups, each sub-pixel group comprises a plurality of sub-pixels, the sensor layer comprises a plurality of sensor groups, each sensor group comprises a plurality of sensors, and the plurality of sensors comprises one or more columns of first sensors arranged along a first direction and one or more columns of second sensors arranged along the first direction, wherein each column of first sensors comprises a plurality of first sensors, each column of second sensors comprises a plurality of second sensors, an orthographic projection of each first sensor on the base substrate overlaps with an orthographic projection of a first number of columns of sub-pixels on the base substrate, and an orthographic projection of each second sensor on the base substrate overlaps with an orthographic projection of a second number of columns of sub-pixels on the base substrate, wherein the first number of columns is greater than the second number of columns; and a plurality of integrated circuit elements, wherein the plurality of integrated circuit elements are electrically connected to the plurality of sub-pixel groups in one-to-one correspondence, and each integrated circuit element is electrically connected to the plurality of sub-pixels in a sub-pixel group electrically connected to the each integrated circuit element, and the plurality of integrated circuit elements are electrically connected to the plurality of sensor groups in one-to-one correspondence, and the each integrated circuit element is electrically connected to the plurality of sensors in a sensor group electrically connected to the each integrated circuit element. Thus, for each integrated circuit element, the number of columns of sub-pixels corresponding to the sensor group electrically connected to the each integrated circuit element is equal to the number of columns of sub-pixels in the sub-pixel group electrically connected to the each integrated circuit element. Therefore, in a case where the integrated circuit elements are electrically connected to the sensors through the touch fanout lines and electrically connected to the sub-pixels through the data fanout lines, the capacitance values of parasitic capacitances generated by the intersection of the touch fanout lines and the data fanout lines at different positions may be made as equal as possible, thereby improving the display effect of the display panel and preventing abnormal display as much as possible.

The above-described design of the embodiment of the present disclosure is beneficial to the wiring of the data fanout lines and the touch fanout lines, thereby saving the wiring space and improving the screen quality of the display panel.

For example, an orthographic projection of each sensor group (also i.e., the plurality of sensors in each sensor group) on the base substrate overlaps with an orthographic projection of a part of sub-pixels in the display layer on the base substrate, wherein the part of sub-pixels may be referred to as sub-pixels corresponding to the sensor group. For another example, an orthographic projection of each sensor on the base substrate overlaps with an orthographic projection of a part of sub-pixels on the base substrate, wherein the part of sub-pixels may be referred to as sub-pixels corresponding to the sensor.

In some embodiments, if any integrated circuit element is electrically connected to a plurality of sensors 700 in a corresponding sensor group and the any integrated circuit element is electrically connected to a plurality of sub-pixels 600 in a corresponding sub-pixel group, the number of columns of sub-pixels overlapped by a plurality of sensors 700 in the corresponding sensor group on an orthographic projection is equal to the number of columns of a plurality of sub-pixels 600 in the corresponding sub-pixel group.

Taking a first integrated circuit element 91 as an example, if the first integrated circuit element 91 is electrically connected to a plurality of sensors 700 in a first sensor group 511, and the first integrated circuit element 91 is electrically connected to a plurality of sub-pixels in a corresponding sub-pixel group (which may be referred to as a first sub-pixel group), the number of columns of sub-pixels overlapped by a plurality of sensors 700 in the first sensor group 511 on an orthographic projection is equal to the number of columns of a plurality of sub-pixels 600 in the first sub-pixel group. The relationships among other integrated circuit elements, sensor groups and sub-pixel groups are also similar, which will not be described in detail here.

It is to be noted that in the embodiment of the present disclosure, orthographic projections of two structures or elements on the base substrate overlap with each other, which may also be referred to as that the two structures or elements overlap with each other. For example, an orthographic projection of a plurality of sensors in a sensor group on the base substrate overlaps with an orthographic projection of a part of sub-pixels on the base substrate, which may be referred to as that the plurality of sensors in the sensor group overlap with the part of sub-pixels. Two structures or elements described here may be adjacent, and may also be not adjacent but separated by another structure or element.

In addition, it is to be noted that although FIG. 7 shows that in each sensor group, the number of columns of the first sensors 710 is greater than the number of columns of the second sensors 720 (FIG. 7 shows eight columns of first sensors 710 and two columns of second sensors 720), the scope of the embodiment of the present disclosure is not limited thereto. For example, in each sensor group, the number of columns of the first sensor may be less than or equal to the number of columns of the second sensor 720.

Furthermore, it is also to be noted that although FIG. 7 shows that in each sensor group, the sensor column where the second sensor 720 is located is at an edge position of the sensor group, the scope of the embodiment of the present disclosure is not limited to a specific position of the sensor column. For example, the sensor column where the first sensor 710 is located and the sensor column where the second sensor 720 is located may be arranged arbitrarily.

In some embodiments, a ratio C of a difference between the first number A of columns and the second number B of columns to the first number A of columns is less than a predetermined value, where

$$C = \frac{A - B}{A} \times 100 \% .$$

For example, the predetermined value is 10%. Of course, those skilled in the art can understand that the predetermined value may also be other values, and the scope of the embodiment of the present disclosure is not limited thereto.

For example, if A is 116, B is 112 and the predetermined value is 10%, then

$$C = \frac{A - B}{A} \times 100 \% = \frac{116 - 112}{116} \times 100 \% = 3.45 \% < 10 \% .$$

In other words, the size difference between the first sensor and the second sensor is less than 10%, and such size difference is not likely to adversely affect the touch function of the display panel.

As shown in FIG. 5, an orthographic projection of each sensor 700 on the base substrate overlaps with an orthographic projection of a part of sub-pixels 600 in the plurality of sub-pixels (in each sub-pixel group) on the base substrate. That is, each sensor corresponds to a part of sub-pixels.

In some embodiments, as shown in FIG. 8, a length L1 of each first sensor 710 in the first direction 101 is greater than a length L2 of each second sensor 720 in the first direction 101. This facilitates that the number of columns of sub-pixels corresponding to each first sensor 710 is greater than the number of columns of sub-pixels corresponding to each second sensor 720.

In some embodiments, as shown in FIG. 7, each column of first sensors 710 comprises at least one first sub-sensor 711 and at least one second sub-sensor 712. As shown in FIG. 8, an orthographic projection of each first sub-sensor 711 on the base substrate overlaps with an orthographic projection of a first number Q1 of rows of sub-pixels on the base substrate, and an orthographic projection of each second sub-sensor 712 on the base substrate overlaps with an orthographic projection of the second number Q2 of rows of sub-pixels on the base substrate, wherein the first number Q1 of rows is greater than the second number Q2 of rows. For example, Q1=36 and Q2=32, so that the first sub-sensor 711 corresponds to 36 rows of sub-pixels and the second sub-sensor 712 corresponds to 32 rows of sub-pixels. This is beneficial to allow that the number of columns of sub-pixels corresponding to the sensor group to which each integrated circuit element is electrically connected is equal to the number of columns of sub-pixels of the sub-pixel group to which the each integrated circuit element is electrically connected.

In some embodiments, as shown in FIG. 7, each column of second sensors 720 comprises at least one third sub-sensor 723 and at least one fourth sub-sensor 724. As shown in FIG. 8, an orthographic projection of each third sub-sensor 723 on the base substrate overlaps with an orthographic projection of a third number Q3 of rows of sub-pixels on the base substrate, and an orthographic projection of each fourth sub-sensor 724 on the base substrate overlaps with an orthographic projection of the fourth number Q4 of rows of sub-pixels on the base substrate, wherein the third number Q3 of rows is greater than the fourth number Q4 of rows. For example, Q3=36 and Q4=32, so that the third sub-sensor 723 corresponds to 36 rows of sub-pixels and the fourth sub-sensor 724 corresponds to 32 rows of sub-pixels. This is beneficial to allow that the number of columns of sub-pixels corresponding to the sensor group to which each integrated circuit element is electrically connected is equal to the number of columns of sub-pixels of the sub-pixel group to which the each integrated circuit element is electrically connected.

In some embodiments, as shown in FIG. 8, the each first sub-sensor 711 and the each third sub-sensor 723 are in a same row, and the first number Q1 of rows is equal to the third number Q3 of rows. This is beneficial to make the dimensions of the sensors in the same row consistent in the second direction, thereby facilitating implementing the array arrangement of the sensors.

In some embodiments, as shown in FIG. 8, the each second sub-sensor 712 and the each fourth sub-sensor 724 are in a same row, and the second number Q2 of rows is equal to the fourth number Q4 of rows. This is beneficial to make the dimensions of the sensors in the same row consistent in the second direction, thereby facilitating implementing the array arrangement of the sensors.

In some embodiments, as shown in FIG. 8, a length L3 of each first sub-sensor 711 in the second direction 102 is greater than a length L4 of each second sub-sensor 712 in the second direction 102. The second direction 102 intersects with the first direction 101. For example, the second direction is perpendicular to the first direction. This is beneficial to allow that the number of rows of the sub-pixels corresponding to the first sub-sensor is greater than the number of rows of the sub-pixels corresponding to the second sub-sensor.

In some embodiments, as shown in FIG. 8, a length L5 of each third sub-sensor 723 in the second direction 102 is greater than a length L6 of each fourth sub-sensor 724 in the fourth direction 102. The second direction 102 intersects with the first direction 101. For example, the second direction is perpendicular to the first direction. This is beneficial to allow that the number of rows of the sub-pixels corresponding to the third sub-sensor is greater than the number of rows of the sub-pixels corresponding to the fourth sub-sensor.

In some embodiments, as shown in FIG. 8, the length L3 of each first sub-sensor 711 in the second direction 102 is equal to the length L5 of each third sub-sensor 723 in the second direction 102, and the length L4 of each second sub-sensor 712 in the second direction 102 is equal to the length L6 of each fourth sub-sensor 724 in the second direction.

In some embodiments, in each sensor group, a number of columns of the one or more columns of first sensors 710 is greater than or equal to a number of columns of the one or more columns of second sensors 720. For example, as shown in FIG. 7, in each sensor group 510 (for example, the first sensor group 511), the number of columns of the first sensors 710 is eight columns and the number of columns of the second sensors 720 is two columns, so that the number of columns of the first sensors 710 is greater than the number of columns of the second sensors 720. This conveniently implements that, for each integrated circuit element, the number of sub-pixels corresponding to the plurality of sensors in the sensor group electrically connected therewith is equal to the number of sub-pixels in the sub-pixel group electrically connected therewith, so that the capacitance values of the above-described parasitic capacitances at different positions are as equal as possible, thereby improving the display effect of the display panel.

It is to be noted that, the number of columns of the first sensors 710 and the number of columns of the second sensors 720 may be adjusted according to actual conditions.

As shown in FIG. 7, each sensor group comprises R1 row of sensors, R2 row of sensors and R3 row of sensors. For example, R1 is 2, R2 is 52 and R3 is 2.

In some embodiments, the one or more columns of first sensors 710 comprise a plurality of columns of first sensors 710, and the one or more columns of second sensors 720 are on at least one side of the plurality of columns of first sensors 710. For example, as shown in FIG. 7, the one or more columns of second sensors 720 comprise a plurality of columns of second sensors 720, wherein one part of columns of second sensors in the plurality of columns of second sensors on one side of the plurality of columns of first sensor 710, and another part of columns of second sensors in the plurality of columns of second sensors are on the other side of the plurality of columns of first sensor 710.

In some embodiments, a number of the plurality of integrated circuit elements is D, where D is a positive integer. The sensor layer comprises E column of sensors, where E is a positive even number. Each integrated circuit element is electrically connected to N columns of sensors, where

$$N = \frac{E}{D}$$

and N is a positive even number. Thus, it is possible to meet the limiting requirements of the number of columns of sensors in the display panel.

In some embodiments, as shown in FIG. 6, areas of any two of the plurality of sensor groups are equal. Thus, it is conveniently implemented that the numbers of columns of sub-pixels corresponding to any two of the plurality of sensor groups are equal.

In some embodiments, an area of the second sensor may be less than an area of the first sensor, or the area of the second sensor may be greater than the area of the first sensor, or the area of the second sensor is equal to the area of the first sensor.

As shown in FIG. 9, each integrated circuit element 90 is electrically connected to the plurality of sub-pixels through a plurality of first wires 810 (that is, the aforementioned data fanout lines), and the each integrated circuit element 90 is electrically connected to the plurality of sensors through a plurality of second wires 820 (that is, the aforementioned touch fanout lines). The plurality of first wires 810 and the plurality of second wires 820 are in different layers or in a same layer. Different first wires 810 are separated by a first insulating layer (not shown), different second wires 820 are separated by a second insulating layer (not shown), and the first wires 810 and the second wires 820 are separated by a third insulating layer (not shown). For example, the first insulating layer, the second insulating layer and the third insulating layer may be the same or different.

It is to be noted that FIG. 9 shows an embodiment in which the first wire 810 and the second wire 820 are in different layers. However, due to the aforementioned arrangement design concerning the sensors (for example, the arrangement design of sensors shown in FIG. 6), an orthographic projection of the first wire 810 in a direction perpendicular to the base substrate coincides with an orthographic projection of the second wire 820 in a direction perpendicular to the base substrate. Therefore, FIG. 9 shows the first wire 810 and the second wire 820 that seem like overlapping at an edge portion.

In some embodiments, numbers of the plurality of first wires 810 electrically connected to any two of the plurality of integrated circuit elements 90 are equal.

In some embodiments, numbers of the plurality of second wires 820 electrically connected to any two of the plurality of integrated circuit elements 90 are equal.

As shown in FIG. 9, a display area corresponding to a plurality of first wires led from each integrated circuit element 90 comprises Q5 columns of sub-pixels. In this way, at the edge of the fanout line part to which each integrated circuit element is electrically connected, the first wire and the second wire are not likely to intersect with each other, and different fanout line parts are relatively regular. In this way, for each integrated circuit element, the number of columns of sub-pixels corresponding to a plurality of sensors in the sensor group electrically connected therewith is equal to the number of columns of a plurality of sub-pixels in the sub-pixel group electrically connected therewith. Thus, in the case where the integrated circuit element is electrically connected to the sensor through the second wire and electrically connected to the sub-pixel through the first wire, the capacitance values of parasitic capacitances generated by the intersection of the second wire and the first wire at different positions may be made as equal as possible, thereby improving the display effect of the display panel, enhancing the image quality of the display panel and preventing abnormal display as much as possible.

The above-described embodiments of the present disclosure may avoid the problem that the touch signal line and the data signal line of one integrated circuit element correspond to different pixel numbers respectively.

Take a horizontal resolution of 3072 for the display panel as an example. For example, the display panel is a display panel with a dual-gate line. A number of data signal lines is 3072*3/2-4608. To select a 576-pin mode, eight integrated circuit elements are required, each integrated circuit element adopts 4608/8-576 pins, and a display area corresponding to data signal lines led from each integrated circuit element comprises 1152 (that is, Q5=1152) columns of sub-pixels. A horizontal resolution of the sensor is SH, where SH/8=N, and N is an even number. For example, N may be 6, 8, 10 or 12, etc. For example, comprehensively considering the size of the sensor. N is selected to be 10. A partition solution is that each sensor in 8 columns of sensors corresponds to 116 columns of sub-pixels, and each sensor in 2 columns of sensors corresponds to 112 columns of sub-pixels, so that each sensor group corresponds to 1152 columns of sub-pixels, which is consistent with the number of columns of sub-pixels corresponding to data signal lines driven by one integrated circuit element. Moreover, the two sizes of sensors have a size difference of less than 10%, which is not likely to adversely affect the touch function.

At a close resolution level, for example, at a resolution level of 3000 pixels in a horizontal direction of the panel, the solution of the embodiment of the present disclosure may support a resolution of 3072, with 80 columns of sensors in a horizontal direction and 56 rows of sensors in a vertical direction, 8 integrated circuit elements are required, and each integrated circuit element drives 576 data signal lines and drives 560 touch signal lines. If a partition solution of sensors in the related art is used, in order to avoid the situation that the data fanout lines and the touch fanout lines intersect with each other between the integrated circuit elements, the horizontal resolution of the display panel may only be adjusted to 3200, with 80 columns of sensors in the horizontal direction and 60 rows of sensors in the vertical direction, 10 integrated circuit elements are required, and each integrated circuit element drives 480 data signal lines and drives 480 touch signal lines. Therefore, by way of the solution of the embodiment of the present disclosure, with a close pixel resolution and the same number of sensors, it is possible to save two integrated circuit elements, and reduce the cost of the integrated circuit elements of the display panel by 20%.

Therefore, with a resolution level similar to a resolution level of the display panel in the related art, the display panel of the embodiment of the present disclosure may save the number of the integrated circuit elements and further reduce the cost on the basis of ensuring the display quality and the touch performance.

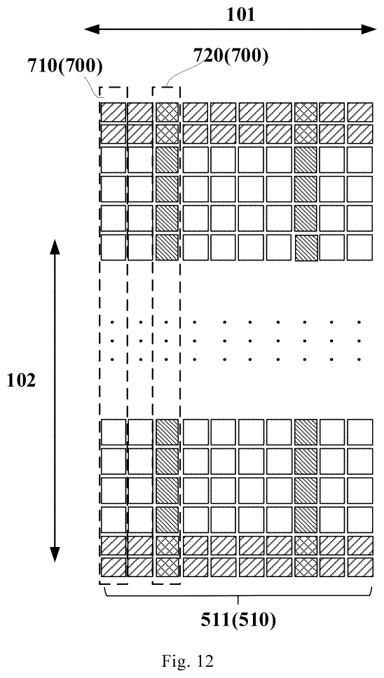

FIG. 10A is a schematic view showing a plurality of first wires and a plurality of second wires of a display panel according to an embodiment of the present disclosure.

FIG. 10A shows a plurality of first wires 810 and a plurality of second wires 820 electrically connected to an integrated circuit element. The plurality of first wires 810 and the plurality of second wires 820 are in different metal layers. The plurality of first wires 810 and the plurality of second wires 820 are separated by an insulating layer (not shown). As shown in FIG. 10A, roots of the plurality of first wires 810 (that is, lower portions of the first wires shown in FIG. 10A) are between roots of the plurality of second wires 820 (that is, lower portions of the second wires shown in FIG. 10A).

FIG. 10B is a schematic view showing a plurality of first wires and a plurality of second wires of a display panel according to another embodiment of the present disclosure.

FIG. 10B shows a plurality of first wires 810 and a plurality of second wires 820 electrically connected to an integrated circuit element. The plurality of first wires 810 and the plurality of second wires 820 are in different metal layers. The plurality of first wires 810 and the plurality of second wires 820 are separated by an insulating layer (not shown). As shown in FIG. 10B, roots of the plurality of second wires 820 (that is, lower portions of the second wires shown in FIG. 10B) are between roots of the plurality of first wires 810 (that is, lower portions of the first wires shown in FIG. 10B).

FIG. 10C is a schematic view showing a plurality of first wires and a plurality of second wires of a display panel according to another embodiment of the present disclosure.

FIG. 10C shows a plurality of first wires 810 and a plurality of second wires 820 electrically connected to an integrated circuit element. The plurality of first wires 810 and the plurality of second wires 820 are in a same metal layer. The plurality of first wires 810 and the plurality of second wires 820 are alternately arranged.

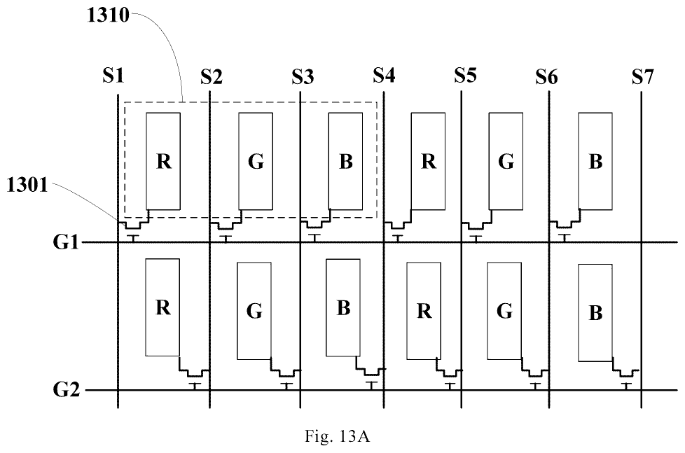

FIG. 11 is a schematic view showing distribution of sensors in a sensor group according to another embodiment of the present disclosure.

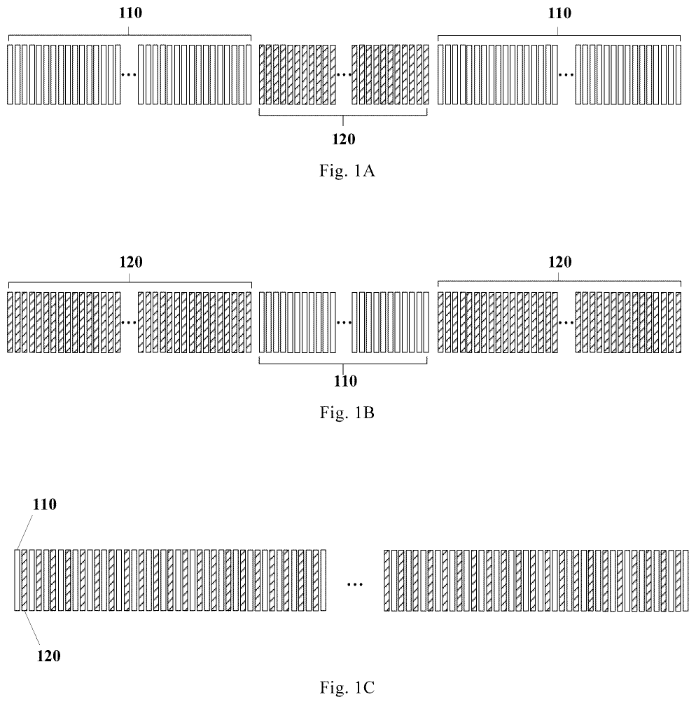

In some embodiments, as shown in FIG. 1, the one or more columns of first sensors 710 comprise a plurality of columns of first sensors 710, and the one or more columns of second sensors 720 are at an intermediate position of the plurality of columns of first sensors 710. It is to be noted that, the intermediate position may be a right intermediate position or other intermediate positions deviating from the right intermediate position.

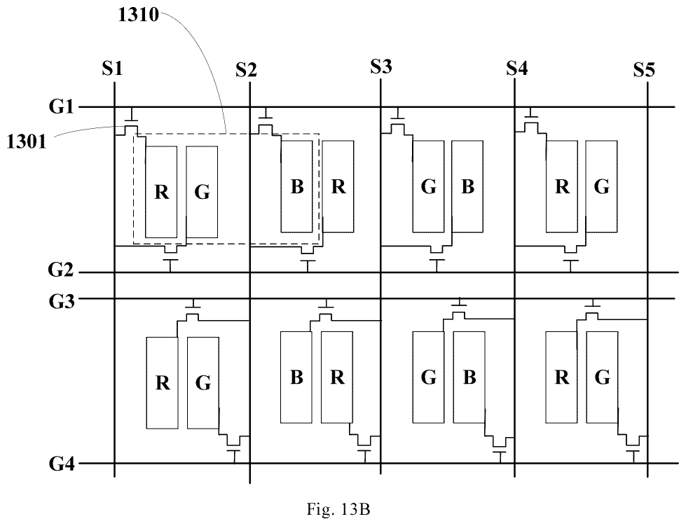

FIG. 12 is a schematic view showing distribution of sensors in a sensor group according to another embodiment of the present disclosure.

In some embodiments, the one or more columns of first sensors 710 comprise a plurality of columns of first sensors 710, and the one or more columns of second sensors 720 comprise a plurality of columns of second sensors 720. One part of columns of second sensors in the plurality of columns of second sensors 720 are between one part of columns of first sensors in the plurality of columns of first sensors 710, and another part of columns of second sensors in the plurality of columns of second sensors 720 are between another part of columns of first sensors in the plurality of columns of first sensors 710.

For example, as shown in FIG. 12, one column of second sensors 720 in the plurality of columns of second sensors 720 is between one part of columns of first sensors 710 (for example, four columns of first sensors 710 located in the left half) in the plurality of columns of first sensors 710, and another column of second sensors 720 in the plurality of columns of second sensors 720 is between another part of columns of first sensors 710 (for example, four columns of first sensors 710 located in the right half) in the plurality of columns of first sensors 710.

In some embodiments, the plurality of columns of first sensors 710 and the plurality of columns of second sensors 720 are staggered.

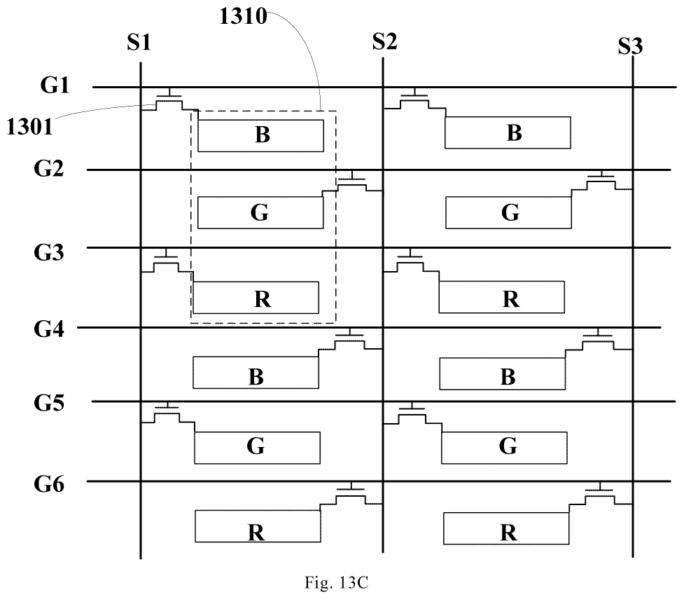

FIG. 13A is a schematic view showing arrangement of sub-pixels of a display panel according to an embodiment of the present disclosure.

As shown in FIG. 13A, the display panel is a display panel with a single-gate line. FIG. 13A shows a plurality of pixels 1310, wherein each of the plurality of pixels 1310 comprises a red sub-pixel R, a green sub-pixel G, and a blue sub-pixel B. Each row of sub-pixels is arranged in an RGB sequence. In the display panel with a single-gate line, each pixel 1310 is electrically connected to one gate line (also referred to as a gate signal line). FIG. 13A shows a plurality of gate lines, such as gate lines G1 and G2.

FIG. 13A shows a plurality of data lines (also referred to as data signal lines), for example, data lines S1, S2, S3, S4, S5, S6 and S7. As shown in FIG. 13A, each column of sub-pixels of the display panel is electrically connected to a corresponding integrated circuit element (not shown in FIG. 13A) through one data line. A number of columns of sub-pixels of the display panel is equal to a number of a plurality of data lines electrically connected to the sub-pixels of the display panel. Each sub-pixel is electrically connected to a corresponding data line through a transistor 1301. For example, a gate of the transistor 1301 is electrically connected to one gate line, a first electrode of the transistor 1301 is electrically connected to one data line, and a second electrode of the transistor 1301 is electrically connected to one sub-pixel.

In some embodiments, a number of the plurality of integrated circuit elements is D, where D is a positive integer. A horizontal resolution of the display panel is H₁ pixels, where H₁ is a positive integer, and each pixel comprises three sub-pixels with different colors (that is, the red sub-pixel R, the green sub-pixel G and the blue sub-pixel B). Each integrated circuit element is electrically connected to at least a part of the plurality of data lines through a plurality of pins, wherein a number of the plurality of pins is M₁, M₁ is a positive integer, and

$${M}_{1} = \frac{{H}_{1} * 3}{D} .$$

For example, in the case that the display panel comprises a plurality of integrated circuit elements, each integrated circuit element is electrically connected to a part of the plurality of data lines through a plurality of pins.

FIG. 13B is a schematic view showing arrangement of sub-pixels of a display panel according to another embodiment of the present disclosure.

As shown in FIG. 13B, the display panel is a display panel with a dual-gate line. FIG. 13B shows a plurality of pixels 1310, wherein each of the plurality of pixels 1310 comprises a red sub-pixel R, a green sub-pixel G, and a blue sub-pixel B. Each row of sub-pixels is arranged in an RGB sequence. In the display panel with a dual-gate line, each pixel 1310 is electrically connected to two gate lines. FIG. 13B shows a plurality of gate lines, such as gate lines G1, G2, G3 and G4.

FIG. 13B shows a plurality of data lines, such as data lines S1, S2, S3, S4 and S5. As shown in FIG. 13B, every two columns of sub-pixels of the display panel are electrically connected to a corresponding integrated circuit element (not shown in FIG. 13B) through one data line. A number of columns of sub-pixels of the display panel is twice a number of a plurality of data lines electrically connected to the sub-pixels of the display panel. Each sub-pixel is electrically connected to a corresponding data line through a transistor 1301. For example, a gate of the transistor 1301 is electrically connected to one gate line, a first electrode of the transistor 1301 is electrically connected to one data line, and a second electrode of the transistor 1301 is electrically connected to one sub-pixel.

In some embodiments, a number of the plurality of integrated circuit elements is D, where D is a positive integer. A horizontal resolution of the display panel is H₂ pixels, where H₂ is a positive integer, and each pixel comprises three sub-pixels with different colors (that is, the red sub-pixel R, the green sub-pixel G and the blue sub-pixel B). Each integrated circuit element is electrically connected to at least a part of the plurality of data lines through a plurality of pins, wherein a number of the plurality of pins is M₂, M₂ is a positive integer, and

$${M}_{2} = \frac{{H}_{2} * 3}{2 * D} .$$

For example, in the case that the display panel comprises a plurality of integrated circuit elements, each integrated circuit element is electrically connected to a part of the plurality of data lines through a plurality of pins.

FIG. 13C is a schematic view showing arrangement of sub-pixels of a display panel according to another embodiment of the present disclosure.

As shown in FIG. 13C, the display panel is a display panel with a triple-gate line. FIG. 13C shows a plurality of pixels 1310, wherein each of the plurality of pixels 1310 comprises a red sub-pixel R, a green sub-pixel G, and a blue sub-pixel B. Each column of sub-pixels is arranged in a BGR sequence. In the display panel with a triple-gate line, each pixel 1310 is electrically connected to three gate lines. FIG. 13C shows a plurality of gate lines, such as gate lines G1, G2, G3, G4, G5 and G6.

FIG. 13C shows a plurality of data lines, such as data lines S1, S2 and S3. As shown in FIG. 13C, a number of columns of pixels of the display panel is equal to a number of a plurality of data lines electrically connected to the pixels of the display panel. Each sub-pixel is electrically connected to a corresponding data line through a transistor 1301. For example, a gate of the transistor 1301 is electrically connected to one gate line, a first electrode of the transistor 1301 is electrically connected to one data line, and a second electrode of the transistor 1301 is electrically connected to one sub-pixel.

In some embodiments, a number of the plurality of integrated circuit elements is D, where D is a positive integer. A horizontal resolution of the display panel is H₃ pixels, where H₃ is a positive integer, and each pixel comprises three sub-pixels with different colors (that is, the red sub-pixel R, the green sub-pixel G and the blue sub-pixel B). Each integrated circuit element is electrically connected to at least a part of the plurality of data lines through a plurality of pins, wherein a number of the plurality of pins is M₃, M₃ is a positive integer, and

$${M}_{3} = \frac{{H}_{3}}{D} .$$

For example, in the case that the display panel comprises a plurality of integrated circuit elements, each integrated circuit element is electrically connected to a part of the plurality of data lines through a plurality of pins.

In an embodiment of the present disclosure, a display device is also provided. The display device comprises the display panel as described previously. For example, the display device may be any product or member having a display function, such as a mobile phone, a tablet computer, a television, a display, a notebook computer, a digital photo frame, a navigator, or the like.

Hereto, various embodiments of the present disclosure have been described in detail. In order to avoid obscuring the concept of the present disclosure, some details commonly known in the art have not been described. From the above descriptions, those skilled in the art may fully understand how to implement the technical solutions disclosed here.

Although some specific embodiments of the present disclosure have been described in detail by way of examples, those skilled in the art should understand that the above examples are only for an illustrative purpose, rather than limiting the scope of the present disclosure. Those skilled in the art should appreciate that modifications to the above embodiments may be made or some technical features may be replaced by equivalents without departing from the scope and spirit of the present disclosure. The scope of the present disclosure is defined by the appended claims.

1. A display panel, comprising:
a base substrate;
a display layer and a sensor layer on the base substrate, wherein the display layer comprises a plurality of sub-pixel groups, each of the plurality of sub-pixel groups comprises a plurality of sub-pixels, the sensor layer comprises a plurality of sensor groups, each of the plurality of sensor groups comprises a plurality of sensors, and the plurality of sensors comprises one or more columns of first sensors arranged along a first direction and one or more columns of second sensors arranged along the first direction, wherein each column of first sensors of the one or more columns of first sensors comprises a plurality of first sensors, each column of second sensors of the one or more columns of second sensors comprises a plurality of second sensors, an orthographic projection of each first sensor of the plurality of first sensors on the base substrate overlaps with an orthographic projection of a first number of columns of sub-pixels on the base substrate, and an orthographic projection of each second sensor of the plurality of second sensors on the base substrate overlaps with an orthographic projection of a second number of columns of sub-pixels on the base substrate, wherein the first number of columns is greater than the second number of columns; and
a plurality of integrated circuit elements, wherein the plurality of integrated circuit elements are electrically connected to the plurality of sub-pixel groups in one-to-one correspondence, and each integrated circuit element of the plurality of integrated circuit elements is electrically connected to the plurality of sub-pixels in a sub-pixel group electrically connected to the each integrated circuit element, and the plurality of integrated circuit elements are electrically connected to the plurality of sensor groups in one-to-one correspondence, and the each integrated circuit element is electrically connected to the plurality of sensors in a sensor group electrically connected to the each integrated circuit element.

2. The display panel according to claim 1, wherein an orthographic projection of each of the plurality of sensors on the base substrate overlaps with an orthographic projection of a part of sub-pixels in the plurality of sub-pixels on the base substrate.

3. The display panel according to claim 1, wherein a length of the each first sensor in the first direction is greater than a length of the each second sensor in the first direction.

4. The display panel according to claim 1, wherein:
the one or more columns of first sensors comprise a plurality of columns of first sensors, and the one or more columns of second sensors are on at least one side of the plurality of columns of first sensors, or the one or more columns of second sensors are at an intermediate position of the plurality of columns of first sensors; or
the one or more columns of first sensors comprise a plurality of columns of first sensors, and the one or more columns of second sensors comprise a plurality of columns of second sensors, wherein one part of columns of second sensors in the plurality of columns of second sensors are between one part of columns of first sensors in the plurality of columns of first sensors, and another part of columns of second sensors in the plurality of columns of second sensors are between another part of columns of first sensors in the plurality of columns of first sensors.

5. The display panel according to claim 1, wherein the each column of first sensors comprises at least one first sub-sensor and at least one second sub-sensor, wherein an orthographic projection of each first sub-sensor of the at least one first sub-sensor on the base substrate overlaps with an orthographic projection of a first number of rows of sub-pixels on the base substrate, and an orthographic projection of each second sub-sensor of the at least one second sub-sensor on the base substrate overlaps with an orthographic projection of a second number of rows of sub-pixels on the base substrate, wherein the first number of rows is greater than the second number of rows.

6. The display panel according to claim 5, wherein the each column of second sensors comprises at least one third sub-sensor and at least one fourth sub-sensor, wherein an orthographic projection of each third sub-sensor of the at least one third sub-sensor on the base substrate overlaps with an orthographic projection of a third number of rows of sub-pixels on the base substrate, and an orthographic projection of each fourth sub-sensor of the at least one fourth sub-sensor on the base substrate overlaps with an orthographic projection of a fourth number of rows of sub-pixels on the base substrate, wherein the third number of rows is greater than the fourth number of rows.

7. The display panel according to claim 6, wherein:
the each first sub-sensor and the each third sub-sensor are in a same row, and the first number of rows is equal to the third number of rows; and
the each second sub-sensor and the each fourth sub-sensor are in a same row, and the second number of rows is equal to the fourth number of rows.

8. The display panel according to claim 5, wherein a length of the each first sub-sensor in a second direction is greater than a length of the each second sub-sensor in the second direction, wherein the second direction intersects with the first direction.

9. The display panel according to claim 6, wherein a length of the each third sub-sensor in a second direction is greater than a length of the each fourth sub-sensor in the second direction, wherein the second direction intersects with the first direction.

10. The display panel according to claim 1, wherein a ratio C of a difference between the first number A of columns and the second number B of columns to the first number A of columns is less than a predetermined value, where
$$C = \frac{A - B}{A} \times 100 \% .$$

11. The display panel according to claim 1, wherein a number of columns of the one or more columns of first sensors is greater than or equal to a number of columns of the one or more columns of second sensors.

12. The display panel according to claim 1, wherein:
a number of the plurality of integrated circuit elements is D, where D is a positive integer;
the sensor layer comprises E column of sensors, where E is a positive even number; and
the each integrated circuit element is electrically connected to N columns of sensors, where
$$N = \frac{E}{D}$$
and N is a positive even number.

13. The display panel according to claim 1, wherein:
the display panel is a display panel with a single-gate line, and a number of columns of sub-pixels of the display panel is equal to a number of a plurality of data lines electrically connected to the sub-pixels of the display panel;
a number of the plurality of integrated circuit elements is D, where D is a positive integer;
a horizontal resolution of the display panel is H₁ pixels, where H₁ is a positive integer, and each of the H₁ pixels comprises three sub-pixels with different colors; and
the each integrated circuit element is electrically connected to at least a part of the plurality of data lines through a plurality of pins, wherein a number of the plurality of pins is M₁, M₁ is a positive integer, and
$${M}_{1} = \frac{{H}_{1} * 3}{D} .$$

14. The display panel according to claim 1, wherein:
the display panel is a display panel with a dual-gate line, and a number of columns of sub-pixels of the display panel is twice a number of a plurality of data lines electrically connected to the sub-pixels of the display panel;
a number of the plurality of integrated circuit elements is D, where D is a positive integer;
a horizontal resolution of the display panel is H₂ pixels, where H₂ is a positive integer, and each of the H₂ pixels comprises three sub-pixels with different colors; and
the each integrated circuit element is electrically connected to at least a part of the plurality of data lines through a plurality of pins, wherein a number of the plurality of pins is M₂, M₂ is a positive integer, and
$${M}_{2} = \frac{{H}_{2} * 3}{2 * D} .$$

15. The display panel according to claim 1, wherein:
the display panel is a display panel with a triple-gate line, and a number of columns of pixels of the display panel is equal to a number of a plurality of data lines electrically connected to the pixels of the display panel;
a number of the plurality of integrated circuit elements is D, where D is a positive integer;
a horizontal resolution of the display panel is H₃ pixels, where H₃ is a positive integer, and each of the H₃ pixels comprises three sub-pixels with different colors; and
the each integrated circuit element is electrically connected to at least a part of the plurality of data lines through a plurality of pins, wherein a number of the plurality of pins is M₃, M₃ is a positive integer, and
$${M}_{3} = \frac{{H}_{3}}{D} .$$

16. The display panel according to claim 1, wherein:
the each integrated circuit element is electrically connected to the plurality of sub-pixels through a plurality of first wires, and the each integrated circuit element is electrically connected to the plurality of sensors through a plurality of second wires, wherein the plurality of first wires and the plurality of second wires are in different layers or in a same layer.

17. The display panel according to claim 16, wherein:
numbers of the plurality of first wires electrically connected to any two of the plurality of integrated circuit elements are equal; and
numbers of the plurality of second wires electrically connected to any two of the plurality of integrated circuit elements are equal.

18. The display panel according to claim 1, wherein areas of any two of the plurality of sensor groups are equal.

19. A display device, comprising: the display panel according to claim 1.
